(19) United States
(12) Patent Application Publication
(10) Pub. No.: US 2022/0093861 A1
(43) Pub. Date: Mar. 24, 2022

(54) SYSTEMS, DEVICES, AND METHODS FOR DEPOSITING A LAYER COMPRISING A GERMANIUM CHALCOGENIDE

(71) Applicants: ASM IP HOLDING B.V., Almere (NL); IMEC VZW, Leuven (BE)

(72) Inventors: Michael Eugene Givens, Helsinki (FI); Yongkook Park, Yongin-si (KR); Mathieu Caymax, Heverlee (BE); Ali Haider, Leuven (BE); Romain Delhougne, Boortmeerbeek (BE)

(21) Appl. No.: 17/478,208

(22) Filed: Sep. 17, 2021

Related U.S. Application Data
(60) Provisional application No. 63/081,541, filed on Sep. 22, 2020.

(51) Int. Cl. H01L 45/00; G11C 13/00

(52) U.S. Cl. CPC H01L 45/1616; H01L 45/144; G11C 13/0004

(57) ABSTRACT

Disclosed are methods and systems for depositing a material comprising a germanium chalcogenide. The material may be selectively deposited onto a surface of a substrate. The deposition process may be a cyclical deposition process. Exemplary devices in which the layers may be incorporated include memory devices.

### CROSS-REFERENCE TO RELATED APPLICATIONS

The present application claims priority to U.S. Provisional Application No. 63/081,541, filed Sep. 22, 2020, which is hereby incorporated by reference in its entirety.

### FIELD

The present disclosure generally relates to the field of semiconductor processing methods, devices, and systems, and to the field of integrated circuit manufacture. In particular, methods and systems suitable for depositing a material comprising a germanium chalcogenide are disclosed. Also disclosed are devices comprising a germanium chalcogenide.

### BACKGROUND

Increasing consumer demands for electronic products that offer superior performance and/or lower cost in turn demands more highly integrated semiconductor devices. Storage class memory (SCM) technology has the potential to bridge the gap between dynamic random-access memory (DRAM) and flash memory technologies, e.g., due to faster operation speed compared to flash memory, and lower bit cost compared to DRAM.

The relatively high cost per bit of two-dimensional (2D) integrated memories may not be compatible with the exponential increase of memory bits in future SCM applications. To overcome such challenges, three-dimensional (3D) semiconductor memory devices having three-dimensionally or vertically arranged memory cells have been recently proposed, but are still having some challenges for SCM applications. To date, 2D stacked SCM architectures have been developed, but are facing cost issues for stacks comprising more than, e.g., four layers. Thus, there is a need for improved 3D semiconductor memory devices. In addition, there is a particular need for simplified methods, processes, and systems for the manufacture of 3D semiconductor memory devices.

The following prior art documents are made of record: J. Mater. Chem. A, 2014, 2, 4865 discloses methods for controlling the nanostructure of bismuth telluride by selective chemical vapour deposition from a single source precursor; Chem. Mater. 2012, 24, 4442-4449 discloses highly selective chemical vapor deposition of tin diselenide thin films onto patterned substrates via single source diselenoether precursors; WO2017160233 discloses a memory device and a method for forming the same; U.S. Pat. No 10,381,409 discloses a three-dimensional phase change memory array including discrete middle electrodes and methods of making the same; U.S. Pat. No. 10,014,213 discloses selective bottom-up metal feature filling for interconnects; U.S. Pat. No. 9,899,291 discloses a method for protecting layer by forming hydrocarbon-based extremely thin film; US2016163725 discloses a selective floating gate semiconductor material deposition in a three-dimensional memory structure; US20170110368 discloses selective bottom-up metal feature filling for interconnects; US 2014/0103145 describes a semiconductor reaction chamber showerhead; US20190221610 describes a three-dimensional semiconductor device and a method of fabricating the same; US20010009138 describes a dynamic blending gas delivery system and method; U.S. Pat. No. 6,039,809 describes a method and apparatus for feeding a gas for epitaxial growth.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods and systems for selectively depositing germanium chalcogenides such as GeSbTe, GeSe, GeTe, ternary germanium chalcogenides, and quaternary germanium chalcogenides such as GeAsSiSe and GeAsSiTe, GeSbTe can be used, for example, for phase-change RRAM (PCRAM). GeSe, GeTe, ternary germanium chalcogenides, and quaternary germanium chalcogenides can be used, for example, for Ovonic Threshold Switching (OTS) selectors.

Described herein is a method for selectively depositing a material, the method comprising, in the following order: providing a substrate comprising a first surface and a second surface in a reaction chamber; providing a surface conditioning agent to the reactor chamber, thereby selectively passivating the first surface and forming a passivated first surface; and, providing a germanium precursor comprising germanium, a pnictogen reactant comprising a pnictogen, and a chalcogen reactant comprising a chalcogen to the reaction chamber, thus selectively depositing the material on the second surface, the material comprising the germanium, the pnictogen, and the chalcogen.

In some embodiments, the germanium precursor comprises a germanium halide.

In some embodiments, the germanium precursor comprises germanium chloride.

In some embodiments, the pnictogen comprises antimony, and the pnictogen reactant comprises an antimony precursor.

In some embodiments, the antimony precursor comprises an antimony halide.

In some embodiments, the antimony precursor comprises antimony chloride.

In some embodiments, the chalcogen comprises tellurium, and the chalcogenide precursor comprises a tellurium precursor.

In some embodiments, the tellurium precursor comprises a tellurium silyl.

In some embodiments, the tellurium precursor comprises a tellurium alkyl silyl.

In some embodiments, the tellurium alkyl silyl comprises a tellurium(II) trimethylsilyl.

In some embodiments, the surface conditioning agent comprises a silyl moiety, and selectively passivating the first surface comprises selectively forming silyl groups on the first surface.

In some embodiments, the surface conditioning agent comprises a methylsilyl.

In some embodiments, the surface conditioning agent comprises trimethylsilyl dimethylamine.

In some embodiments, the step of providing a germanium precursor, a pnictogen reactant, and a chalcogen reactant to the reaction chamber comprises a cyclic deposition process comprising a plurality of cycles, the cycles comprising a plurality of pulses, the plurality of pulses comprising, in any order: providing the germanium precursor to the reaction chamber in a germanium precursor pulse; providing the pnictogen reactant to the reaction chamber in a pnictogen reactant pulse; and, providing the chalcogen reactant to the reaction chamber in a chalcogen reactant pulse.

In some embodiments, the germanium precursor pulse, the pnictogen reactant pulse, and/or the chalcogen reactant pulse are separated by other pulses by means of a purge.

In some embodiments, the pnictogen reactant pulse precedes the germanium precursor pulse.

In some embodiments, the second surface comprises a metal nitride or a metal.

In some embodiments, the second surface comprises titanium nitride or tungsten.

In some embodiments, the first surface comprises an oxide, such as silicon oxide.

Further described herein is a method for manufacturing an intermediate memory device structure, the method comprising: providing a substrate comprising, on an upper surface, a multi-layer stack comprising horizontally alternating first layers and second layers; the first layers comprising a first material, the first material comprising a dielectric material; the second layers comprising extremities, the second layers comprising, at least on their extremities, a metal or a metal nitride, the metal or the metal nitride forming an electrode; forming an opening in the multi-layer stack, thereby exposing the metal or the metal nitride; selectively depositing a material comprising germanium, a pnictogen, and a chalcogenide on the metal or the metal nitride by means of a method as described herein.

In some embodiments, the method further comprises, before depositing the germanium chalcogenide, a step of partially recessing the metal or the metal nitride.

In some embodiments, the method further comprises depositing a further metal or a further metal nitride on the germanium chalcogenide, thus forming a second electrode.

In some embodiments, the opening is a trench extending throughout the thickness of the multi-layer stack.

In some embodiments, the intermediate memory device structure is comprised in a phase change random access memory (PCRAM).

Further described herein is a method for manufacturing a memory device, the method comprising: providing a fin comprising a plurality of alternating first layers and second layers, the first layers comprising a first surface, the second layers comprising a plurality of wordlines having a second surface, the second surface comprising a metal surface or a metal nitride surface; selectively depositing a plurality of phase change layers by depositing a material comprising germanium, a pnictogen, and a chalcogenide on the second surface by means of a method as described herein; forming a plurality of electrodes contacting the plurality of phase change structures; forming a plurality of selectors overlying the plurality of electrodes; forming a plurality of bitlines overlying the plurality of selectors; and, forming a plurality of contacts to the wordlines and forming a plurality of contacts to the bitlines, thus forming a memory device.

In some embodiments, forming a plurality of contacts to the wordlines comprises providing a staircase structure in which sequential wordlines are sequentially contacted.

In some embodiments, the contacts are shaped as separated lines or dots.

In some embodiments, the plurality of bitlines electrically connect the fin to one or more neighboring fins.

Further described herein is a system comprising one or more reactor chambers comprising a substrate holder for holding a substrate; a blocking agent storage module comprising a blocking agent, the blocking agent comprising an alkylaminosilane; a germanium precursor storage module comprising a germanium precursor; a pnictogen reactant storage module comprising a pnictogen reactant; a chalcogen reactant storage module comprising a chalcogen reactant; and, an injector for injecting the blocking agent, the germanium precursor, the pnictogen reactant, and the chalcogen reactant into the reaction chamber.

In some embodiments, the system further comprises a controller; the controller being configured for causing the system to provide the blocking agent to the reaction chamber in an area-selective blocking agent pulse; to provide a sequence of deposition pulses to the reaction chamber after the area-selective blocking pulse; the sequence of deposition pulses comprising a germanium pulse, an antimony pulse, and a tellurium pulse; the germanium pulse comprising the provision of the germanium precursor from the germanium precursor storage module to the reaction chamber; the pnictogen pulse comprising the provision of the pnictogen reactant from the pnictogen reactant storage module to the reaction chamber; the chalcogen pulse comprising the provision of the chalcogen reactant from the chalcogen precursor storage module to the reaction chamber.

In some embodiments, the controller is configured for causing the system to perform a method as described herein.

In some embodiments, the system further comprises a manifold, the manifold having an internal bore, at least one distribution channel extending generally in a plane intersecting the longitudinal axis of the bore, and a plurality of internal supply channels connecting the distribution channel and the bore, wherein the distribution channel is connected to the blocking agent storage module, the germanium precursor storage module, the pnictogen reactant storage module, and the chalcogen reactant storage module, and wherein the manifold is configured to deliver the blocking agent, the germanium precursor, the pnictogen reactant, and the chalcogen reactant to a reactor chamber.

In some embodiments, the system further comprises a showerhead for providing the blocking agent, the germanium precursor, the pnictogen reactant, and the chalcogenide reactant to the reaction chamber.

In some embodiments, the controller is configured for controlling a temperature of the blocking agent storage module, for controlling a temperature of the germanium precursor storage module, for controlling a temperature of the pnictogen reactant storage module, and/or for controlling a temperature of the chalcogen reactant storage module.

In some embodiments, the controller is configured for controlling a pressure of the blocking agent storage module, for controlling a pressure of the germanium precursor storage module, for controlling a pressure of the pnictogen reactant storage module, and/or for controlling a pressure of the chalcogen reactant storage module.

In some embodiments, the system comprises a plurality of blocking agent storage modules, the plurality of blocking agent storage modules each comprising an identical blocking agent, wherein the controller is configured for causing the system to simultaneously inject blocking agent, during the area-selective blocking agent pulse, from each of the blocking agent storage modules into the reaction chamber.

In some embodiments, the system comprises a plurality of germanium precursor storage modules, the plurality of germanium precursor storage modules each comprising an identical germanium precursor, wherein the controller is configured for causing the system to simultaneously inject germanium precursor, during the germanium pulses, from each of the germanium precursor storage modules into the reaction chamber.

In some embodiments, the system comprises a plurality of pnictogen reactant storage modules, the plurality of pnictogen reactant storage modules each comprising an identical pnictogen reactant, wherein the controller is configured for causing the system to simultaneously inject the pnictogen reactant, during the pnictogen pulses, from each of the pnictogen reactant storage modules into the reaction chamber.

In some embodiments, the system comprises a plurality of chalcogen reactant storage modules, the chalcogen reactant storage modules each comprising an identical chalcogen reactant, wherein the controller is configured for causing the system to simultaneously inject the chalcogen reactant, during the chalcogen pulses, from each of the chalcogen reactant storage modules into the reaction chamber.

In some embodiments, the system further comprises a blocking agent buffer module, the blocking agent buffer module being configured to receive the blocking agent from the blocking agent storage module, and the blocking agent buffer module being configured to provide the blocking agent to the reaction chamber.

In some embodiments, the system further comprises a germanium precursor buffer module, the germanium precursor buffer module being configured to receive the germanium precursor from the germanium precursor storage module, and the germanium precursor buffer module being configured to provide the germanium precursor to the reaction chamber.

In some embodiments, the system further comprises a pnictogen reactant buffer module, the pnictogen reactant buffer module being configured to receive the pnictogen reactant from the pnictogen reactant storage module, and the pnictogen reactant buffer module being configured to provide the pnictogen reactant to the reaction chamber.

In some embodiments, the system further comprises a chalcogen reactant buffer module, the chalcogen reactant buffer module being configured to receive the chalcogen reactant from the chalcogen reactant storage module, and the chalcogen reactant buffer module being configured to provide the chalcogen reactant to the reaction chamber.

In some embodiments, the blocking agent buffer module is configured to receive the blocking agent from more than one blocking agent storage module and to provide the blocking agent to the reaction chamber; the germanium precursor buffer module is configured to receive the germanium precursor from more than one germanium precursor storage module and to provide the germanium precursor to the reaction chamber; the pnictogen reactant buffer module is configured to receive the pnictogen reactant from more than one pnictogen reactant storage module and to provide the pnictogen reactant to the reaction chamber; and/or the chalcogen reactant buffer module is configured to receive the chalcogen reactant from more than one chalcogen reactant storage module and to provide the chalcogen reactant to the reaction chamber.

In some embodiments, the system comprises more than one blocking agent buffer module, each blocking agent buffer module being configured to receive blocking agent from a blocking agent storage module and to provide the blocking agent to the reaction chamber; more than one germanium precursor buffer module, each germanium precursor buffer module being configured to receive germanium precursor from a germanium precursor storage module and to provide the germanium precursor to the reaction chamber; more than one pnictogen reactant buffer module, each pnictogen reactant buffer module being configured to receive pnictogen reactant from a pnictogen reactant storage module and to provide the pnictogen reactant to the reaction chamber; and/or more than one chalcogen reactant buffer module, each chalcogen reactant buffer module being configured to receive chalcogen reactant from a chalcogen reactant storage module and to provide the chalcogen reactant to the reaction chamber.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWINGS

A more complete understanding of the embodiments of the present disclosure may be derived by referring to the detailed description and claims when considered in connection with the following illustrative figures.

FIG. 1 illustrates a cross-sectional view of an intermediate structure as part of a method of manufacturing a three-dimensional (3D) semiconductor memory device according to some embodiments.

FIG. 2 illustrates a three-dimensional view of a part of a three-dimensional (3D) semiconductor memory device according to some embodiments.

FIGS. 3, 4, 5a, 5b, 6b, 7a, 7b, 8, and 9 illustrate cross-sectional views of intermediate structures at different stages of a method of manufacturing a three-dimensional (3D) semiconductor memory device according to some embodiments.

FIG. 6a illustrates a comparative example showing conventional techniques for manufacturing a part of a 3D semiconductor memory device.

FIG. 10 illustrates a three-dimensional view of a part of a three-dimensional (3D) semiconductor memory device according to some embodiments.

FIGS. 11a and 11b illustrate three-dimensional views of a part of a three-dimensional (3D) semiconductor memory device according to some embodiments.

FIGS. 12a and 12b are schematic flow charts illustrating methods according to some embodiments.

FIG. 13 shows a flow chart illustrating an embodiment of a method for depositing a material comprising germanium, a pnictogen, and a chalcogenide. In this figures, the following numbering is adhered to: 1300—method; 1302—step of providing a substrate within a reaction chamber; 1304—deposition process.

FIGS. 14-16 show embodiments of a system as described herein. In these figures, the following numbering is adhered to: 1400—system; 1402—one or more reaction chambers; 1404—blocking agent storage module; 1405—germanium precursor storage module; 1406—pnictogen reactant storage module; 1408—chalcogen reactant storage module; 1410—exhaust; 1412—controller; 1414—blocking agent gas line; 1415—germanium precursor gas line;—1416—pnictogen reactant gas line; 1418—chalcogen reactant gas line; 1454—blocking agent buffer module; 1455—germanium precursor buffer module; 1456—pnictogen reactant buffer module; 1458—chalcogen reactant buffer module.

As illustrated in the figures, the sizes of the elements, features, and other structures may be exaggerated or not depicted proportionally for illustrative purposes. Thus, the figures are provided to illustrate the general elements of the embodiments.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include helium, argon, and any combination thereof. In some cases, an inert gas can include nitrogen and/or hydrogen.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate/and/or embedded in a device manufactured on that substrate. A film or layer may comprise material or a layer with pinholes and/or isolated islands. A film or layer may be at least partially continuous.

As used herein, a “structure” can be or include a substrate as described herein. Structures can include one or more layers overlying the substrate, such as one or more layers formed according to a method as described herein. Device portions can be or include structures.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to a sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reactor chamber in between two pulses of gasses which react with each other. For example, a purge, e.g. using nitrogen gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used e.g. in the temporal sequence of providing a first precursor to a reactor chamber, providing a purge gas to the reactor chamber, and providing a second precursor to the reactor chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

As used herein, a vertical stack may be understood as a structure comprising at least two layers arranged on top of each other, as seen in a vertical direction relative an underlying semiconductor substrate.

As used herein, a lateral stack may refer to at least two layers arranged beside each other, in a lateral or horizontal direction.

As used herein, recessing may refer to a material removal process resulting in concavity or space extending e.g., into a vertical stack of alternating layers, or in a lateral stack of layers. This may, for example, include removing parts of a layer of a first layer type, while leaving adjacent layers of a second layer type intact, or vice versa. Recessing may, for example, be done by an etching process.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments.

As used herein, reference to “each” of a particular element (e.g., “each recess”) may refer to two or more of the elements, and may or may not refer to every one of the elements in the device. For example, “each recess” may refer to individual recesses comprised in a plurality of recesses and it need not necessarily refer all recesses in the device.

As used herein, a selector element may refer to an element that tends to conduct current above certain voltage levels. A selector element may, e.g., include an OTS device, a mixed ionic-electronic conduction (MIEC) element, and/or a diode.

It will be appreciated that a memory device or cell, as used in the context of the disclosed technology, may generally refer to the specific memory structure capable of storing two different logic states, such as a logic “1” and a logic “0”. As used herein, a semiconductor device or semiconductor memory device may generally refer to the resulting 3D device, comprising a plurality of individual cells (or memory devices).

In this disclosure, any defined meanings do not necessarily exclude ordinary and customary meanings in some embodiments.

Described herein is a method for selectively depositing a material on a substrate. Otherwise stated, described herein is a method for forming a layer on a substrate. The material may be suitably deposited in a reactor chamber. The material may form a layer and may be deposited, for example, using a method such as vacuum evaporation deposition, Molecular Beam Epitaxy (MBE), different variants of Chemical Vapor Deposition (CVD) (including low-pressure and organometallic CVD and plasma-enhanced CVD), and Atomic Layer Deposition (ALD). Alternatively, the material may be deposited by means of a hybrid process that comprises characteristics of more than one of these methods. Thus, the method comprises the application of a deposition process. In some embodiments, the deposition process comprises a chemical vapor deposition process. In some embodiments, the deposition process comprises a cyclical deposition process. In some embodiments, the process comprises a cyclical chemical vapor deposition process. Additionally or alternatively, the cyclical deposition process can include an atomic layer deposition process. In some embodiments, the cyclical deposition process has characteristics of both chemical vapor deposition and atomic layer processes, i.e. the cyclical deposition process may be a hybrid cyclical process. In some embodiments, the deposition process comprises a thermal process, i.e. a process that does not use plasma-activated species.

A monocrystalline silicon wafer may be a suitable substrate. Other substrates may be suitable well, e.g. monocrystalline germanium wafers, gallium arsenide wafers, quarz, sapphire, glass, steel, aluminum, silicon-on-insulator substrates, plastics, etc.

The substrate comprises a first surface and a second surface. The method comprises providing a surface conditioning agent to the reactor chamber. The surface conditioning agent then passivates the first surface. The method comprises providing a germanium precursor, a pnictogen reactant, and a chalcogen reactant to the reaction chamber. The germanium precursor comprises germanium, the pnictogen reactant comprises a pnictogen, and the chalcogen reactant comprises a chalcogen. Accordingly, a layer is formed on the second surface. In other words, a material is selectively deposited on the second surface. In other words, a layer is selectively formed on the second surface, i.e. the layer is formed on the second surface and substantially less of the layer is deposited on the first surface. Stated yet differently, the precursor and reactants react substantially more on the second surface than on the first surface such that the material is selectively deposited on the second surface. The material comprises the germanium, the pnictogen, and the chalcogen. Such methods may be particularly useful in the fabrication of memory devices: the present selective methods allow reducing the total number of process steps. For example, a memory element may be manufactured without need for any subsequent etching steps which would be needed when the memory element is formed from a blanket layer. Thus, the present methods may be useful, for example, for the manufacture of improved 3D semiconductor devices, such as 3D storage class memory (SCM) devices, and methods of manufacturing the same. The 3D semiconductor devices may comprise a memory cell structure, which may, e.g. be a 1S1R cell, comprising one selector element and one resistor element.

Certain implementations of the disclosed manufacturing process can reduce the bit cost for manufacturing high density memories and can be compatible with various selector and memory technologies, such as, e.g., an ovonic threshold switching (OTS) device, volatile conductive bridge (VCB), Mott-based, diodes for selectors, and oxide-based resistive random access memory (OxRAM), conductive-bridging random access memory CBRAM), phase-change memory (PCM), and ferroelectric random access memory (FeRAM) based memory cells. The manufacturing process in some embodiments can further allow for the manufacturing order of the memory element and the selector element to be interchanged, which may allow for improved device operation, compatibility, and simplified process flow.

In some embodiments, the germanium precursor comprises a germanium.

In some advantageous embodiments, the germanium halide comprises germanium chloride. The germanium halide may be stabilized, for example, by means of a stabilizer such as dioxane.

In some embodiments, the germanium precursor comprises GeH₂Cl₂.

In some embodiments, the pnictogen comprises antimony, and the pnictogen reactant comprises an antimony precursor. In some embodiments, the pnictogen reactant comprises a pnictogen halide. In some embodiments, the pnictogen reactant comprises a pnictogen chloride. In some embodiments, the antimony reactant comprises an antimony halide. In some embodiments, the antimony halide comprises antimony chloride.

In some embodiments, the chalcogen comprises tellurium, and the chalcogen reactant comprises a tellurium reactant. In some embodiments, the chalcogen reactant comprises a chalcogen silyl. In some embodiments, the chalcogen reactant comprises a chalcogen alkyl silyl. In some embodiments, the chalcogen reactant comprises a chalcogen(II) trimethylsilyl. In some embodiments, the tellurium reactant comprises a tellurium silyl. In some embodiments, the tellurium silyl comprises a tellurium alkyl silyl. In some embodiments, the tellurium alkyl silyl comprises tellurium(II) trimethylsilyl. In some embodiments, the tellurium alkyl silyl comprises ((C₂H₅)₃Si)₂Te or (C₂H₅)₃SiTe(CH₃)₃Si.

In some embodiments, the surface conditioning agent comprises a silyl moiety, and selectively passivating the first surface comprises selectively forming silyl groups on the first surface. In other words, selectively passivating the first surface may comprise subjecting the substrate to a gas phase comprising molecules having a silyl functional group, and forming a higher density of silyl groups on the first surface compared to the second surface.

In some embodiments, the surface conditioning agent comprises an alkylsilyl moiety. In some embodiments, the surface conditioning agent comprises a methylsilyl moiety.

In some embodiments, the surface conditioning agent comprises an alkylsilyl moiety and an alkylamine moiety. In some embodiments, the surface conditioning agent comprises trimethylsilyl dimethylamine.

In some embodiments, the present method is performed at a temperature of at least 25° C. to at most 300° C., or of at least 25° C. to at most 50° C., or of at least 50° C. to at most 100° C., or of at least 100° C. to at most 200° C., or of at least 200° C. to at most 300° C. Advantageously, the present method is performed at a temperature of at least 50° C. to at most 150° C. More advantageously, the present method is performed at a temperature of at least 70° C. to at most 100° C.

In some embodiments, the present methods are performed at a temperature of at least 0.1 Torr to at most 100 Torr, or of at least least 0.1 Torr to at most 1 Torr, or of at least 1 Torr to at most 10 Torr, or of at least 10 Torr to at most 100 Torr. In advantageous embodiments, the present methods are performed at a temperature of at least 1 Torr to at most 5 Torr.

In some embodiments, the step of providing a germanium precursor, a pnictogen reactant, and a chalcogen reactant to the reaction chamber comprises a cyclic deposition process. In some embodiments, the germanium precursor is provided first. Such a cyclic deposition process comprises a plurality of cycles. The cycles comprise a plurality of pulses. The plurality of pulses comprise: providing the germanium precursor to the reaction chamber in a germanium precursor pulse; providing the pnictogen reactant to the reaction chamber in a pnictogen reactant pulse; and, providing the chalcogen reactant to the reaction chamber in a chalcogen reactant pulse. Suitably, the pulses may be performed in any order. In some embodiments, the germanium precursor pulse precedes the pnictogen reactant pulse. In some embodiments, the pnictogen reactant pulse precedes the chalcogen reactant pulse. In some embodiments, the pnictogen reactant pulse precedes the germanium precursor pulse. In some embodiments, the chalcogen reactant pulse precedes the pnictogen reactant pulse.

In some embodiments, a pnictogen reactant pulse is provided after the blocking agent pulse and before the germanium precursor pulse. This may suppress unfavorable disproportionation reactions. For example when germanium chloride is used as a precursor, the following disproportionation reaction is preferably avoided: 2 GeCl₂->Ge (solid)+GeCl₄ (gas).

In some embodiments, the germanium precursor pulses, the pnictogen reactant pulses, and/or the chalcogen reactant pulses are separated by other pulses by means of purges. Thus, in some embodiments, and in any order, the germanium precursor pulse and the pnictogen reactant pulse are separated by a purge. In some embodiments, in any order, the germanium precursor pulse and the chalcogen reactant pulse are separated by a purge. In some embodiments, in any order, the pnictogen reactant pulse and the chalcogen reactant pulse are separated by a purge.

In some embodiments, the step of providing the surface conditioning agent to the reactor chamber and the step of providing a germanium precursor, a pnictogen reactant, and a chalcogen reactant to the reaction chamber are separated by a purge.

Purging the reaction chamber can involve removing one or more vapor phase precursors, vapor phase reactants, and/or vapor phase byproducts from the reaction chamber such as by evacuating the chamber with a vacuum pump and/or by replacing the gas inside the reactor with a gas such as an inert gas, e.g. a noble gas such as argon, or nitrogen. Typical purging times for a single wafer reactor may be from about 0.05 to 20 seconds. However, other purge times can be utilized if desired, such as when depositing a material over extremely high aspect ratio structures or other structures with complex surface morphology is needed, or when a high volume batch reactor is employed.

In some embodiments, the blocking agent pulse has a duration from at least 0.1 s to at most 20.0 s.

In some embodiments, the germanium precursor pulse has a duration from at least 20 s to at most 150 s, or from at least 40 s to at most 100 s, or from at least 50 s to at most 80 s. In some embodiments, the germanium precursor pulse has a duration of from at least 0.1 s to at most 200 s, or of at least 0.1 s to at most 0.2 s, or of at least 0.2 s to at most 0.5 s, or of at least 0.5 s to at most 1.0 s, or of at least 1.0 s to at most 2.0 s, or of at least 2.0 s to at most 5.0 s, or of at least 5.0 s to at most 10 s, or of at least 10 s to at most 20 s, or of at least 20 s to at most 50 s, or of at least 50 s to at most 100 s, or of at least 100 s to at most 200 s.

In some embodiments, the pnictogen reactant pulse lasts from at least 0.1 s to at most 20 s.

In some embodiments, the chalcogen reactant pulse lasts from at least 0.1 s to at most 20 s.

In some embodiments, the second surface comprises a metal nitride or a metal.

In some embodiments, the second surface comprises titanium nitride

In some embodiments, the second surface comprises tungsten.

In some embodiments, the first surface comprises an oxide. In some embodiments, the first surface comprises silicon oxide. In some embodiments, the first surface comprises a high-k dielectric, e.g. a high-k oxide, e.g. HfO₂ or Al₂O₃.

In the following paragraphs, process conditions are given for a reactor chamber volume of 1 liter and for 300 mm wafers. The skilled person understands that these values can be readily extended to other reactor chamber volumes and wafer sizes.

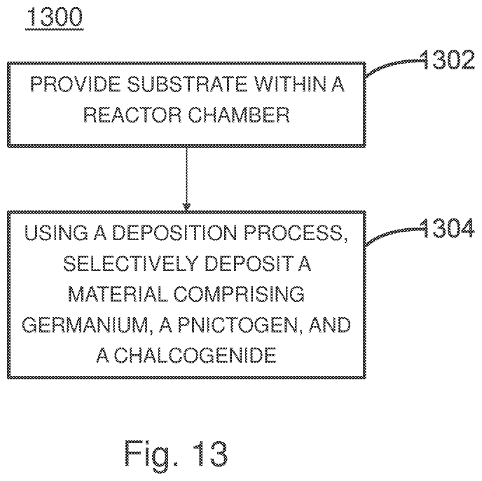

FIG. 13 illustrates a method 1300 in accordance with exemplary embodiments of the disclosure.

Method 1300 includes the steps of providing a substrate within a reaction chamber of a reactor (step 1302) and using a deposition process, depositing a material onto a surface of the substrate (step 1304). Advantageously, the deposition process comprises a selective cyclical deposition process as described herein. The material comprises germanium, a pnictogen, and a chalcogen.

During step 1302, a substrate is provided within a reaction chamber. The reaction chamber used during step 1302 can be or include a reaction chamber of a chemical vapor deposition reactor system configured to perform a deposition process, e.g. a cyclical deposition process. This notwithstanding, the reactor chamber may also be a reactor chamber of an atomic layer deposition system. The reaction chamber can be a standalone reaction chamber or part of a cluster tool.

Step 1302 can include heating the substrate to a desired deposition temperature within the reaction chamber.

In addition to controlling the temperature of the substrate, a pressure within the reaction chamber may also be regulated.

During step 1304, a material is deposited onto a surface of the substrate using a deposition process. The deposition process may be a cyclical deposition process. The material comprises germanium, a pnictogen, and a chalcogenide. As noted above, the cyclical deposition process can include cyclical CVD, ALD, or a hybrid cyclical CVD/ALD process. For example, in some embodiments, the growth rate of a particular ALD process may be low compared with a CVD process. In some embodiments, one or more precursor and/or reactants may be continuously provided to the reaction chamber while other precursors and/or reactants are provided to the reaction chamber in pulses. One approach to increase the growth rate may be that of operating at a higher deposition temperature than that typically employed in an ALD process, resulting in some portion of a chemical vapor deposition process, but still taking advantage of the sequential introduction of reactants. Such a process may be referred to as cyclical CVD. In some embodiments, a cyclical CVD process may comprise the introduction of two or more reactants into the reaction chamber, wherein there may be a time period of overlap between the two or more reactants in the reaction chamber resulting in both an ALD component of the deposition and a CVD component of the deposition. This is referred to as a hybrid process. In accordance with further examples, a cyclical deposition process may comprise the continuous flow of one reactant/precursor and the periodic pulsing of a second reactant into the reaction chamber. In some embodiments, the deposition process may be a non-cyclical process, i.e. a process in which the precursors and reactants are continuously provided to the reaction chamber.

In accordance with some examples of the disclosure, the deposition process is a thermal deposition process. In these cases, the deposition process does not include use of a plasma to form activated species for use in the deposition process.

In the case of thermal cyclical deposition processes, a duration of the step of providing reactant to the reaction chamber can be relatively long to allow the reactant to react with the precursor or a reaction product derived from the precursor. For example, the duration can be greater than or equal to 5 seconds or greater than or equal to 10 seconds or between about 5 and 10 seconds. Alternatively, the step of providing the reactant to the reaction chamber can be shorter, e.g. from at least 0.1 s to at most 5.0 s, or from at least 0.2 s to at most 2 s, or from at least 0.5 s to at most 1.0 s.

As part of step 1304, the reaction chamber can be purged using a vacuum and/or an inert gas to mitigate gas phase reactions between reactants and enable self-saturating surface reactions—e.g., in the case of temporal ALD. Additionally or alternatively, the substrate may be moved to separately contact a first vapor phase reactant and a second vapor phase reactant, e.g. in the case of spatial ALD. Surplus chemicals and reaction byproducts, if any, can be removed from the substrate surface or reaction chamber, such as by purging the reaction space or by moving the substrate, before the substrate is contacted with the next reactive chemical. The reaction chamber can be purged after the step of providing a precursor to the reaction chamber and/or after the step of providing a reactant to the reaction chamber.

The present methods can optionally be carried out in a reaction chamber or space connected to larger system such as a cluster tool. In a cluster tool, because each reaction space is dedicated to one type of process, the temperature of the reaction space in each module can be kept constant, which improves the throughput compared to a reactor in which is the substrate is heated to the process temperature before each run. A stand-alone reactor can be equipped with a load-lock. In that case, it is not necessary to cool down the reaction chamber or space between each run. These processes can also be carried out in a reactor designed to process multiple substrates simultaneously, e.g., a mini-batch type showerhead reactor.

Further described herein is a method for manufacturing an intermediate memory device structure. The method comprises providing a substrate comprising, on an upper surface, a multi-layer stack comprising horizontally alternating first layers and second layers. The first layers comprise a first material. The first material comprises a dielectric material. The second layers comprise extremities. The second layers comprise, at least on their extremities, a metal or a metal nitride. The metal or metal nitride forms an electrode.

The method further comprises forming an opening in the multi-layer stack. Thus, the metal or the metal nitride is exposed. Optionally, the metal or the metal nitride is recessed. Then, a material comprising germanium, a pnictogen, and a chalcogenide is deposited selectively on the metal or the metal nitride. Suitably, this layer may be deposited by means of a method as described elsewhere herein.

In some embodiments, the method further comprises depositing a further metal or a further metal nitride on the germanium chalcogenide, thus forming a second electrode.

In some embodiments, the opening is a trench extending throughout the thickness of the multi-layer stack.

In some embodiments, the intermediate memory device structure is comprised in a phase change random access memory (PCRAM), a resistive random access memory (RRAM), a filamentary-oxide-based resistive memory (OXRAM), or a conductive bridging random access memory (CBRAM). In some embodiments, the present method is used for manufacturing an OTS selector, e.g. for use in RRAM, OXRAM or CBRAM. In some embodiments, the present method is used for forming a phase change material, e.g. for use in PCRAM.

Further described is a method for manufacturing a memory device. The method comprises providing a fin comprising a plurality of alternating first layers and second layers. The plurality of alternating first and second layers may, for example, be formed from a nitride oxide multilayer stack, e.g. a silicon nitride-silicon oxide multilayer stack, in which one of the nitride or oxide layers is recessed, and thereafter at least partially filled with a conductive material. For example, the first and second layers may be formed from a silicon oxide/silicon nitride stack, or from a dielectric/semiconductor stack, or from a stack comprising alternating layers of a first dielectric and a second dielectric. Alternatively, the first layers may comprise a dielectric and the second layers may comprise conductive material such as a doped semiconductor or a metal, in which case there is no need for recessing the second layers and then at least partially refilling them with a conductive material. Note that any combination of a great variety of materials may be used to form the first layers and the second layers, provided that the selected materials feature an etch contrast with respect to each other. Suitably, the first layers may be formed entirely from a dielectric, and the second layers may comprise a dielectric, semiconductor, metal, or a combination thereof.

In some embodiments, the first layers comprise a dielectric and the second layers comprise a semiconductor. In some embodiments, the first layers comprise a dielectric and the second layers comprise another dielectric.

The first layers comprise a first surface. The second layers comprise a plurality of wordlines having a second surface. The second surface comprises a metal surface or a metal nitride surface. A suitable material for the first surface may, for example, include titanium nitride and/or tungsten. This may advantageously provide a relatively low electrical resistance.

The method further comprises selectively depositing a plurality of phase change layers comprising a material comprising germanium, a pnictogen, and a chalcogenide on the second surface by means of a method as described elsewhere herein. The method further comprises forming a plurality of electrodes contacting the plurality of phase change layers, and forming a plurality of selectors overlying the plurality of electrodes. Then, a plurality of bitlines overlying the plurality of selectors may be formed. Finally, a plurality of contacts to the wordlines and a plurality of contacts to the bitlines may be formed. Thus, a memory device is or a part thereof may be manufactured.

In some embodiments, forming the plurality of contacts to the wordlines comprises providing a staircase structure in which sequential wordlines are sequentially contacted. In other words, sequential wordlines are contacted in sequential stairs. These connections can allow each memory cell, or 1S1R structure, to be individually addressed.

In some embodiments, the contacts are shaped as separated lines or dots.

In some embodiments, the plurality of bitlines electrically connect the fin to one or more neighboring fins. Such connecting bitlines may be formed, for example, using a process including a combination of lithography and etching so as to achieve contact structures configured to selectively contact specific cells of the fins.

In some embodiments, the selector element may be formed by providing a selector element material in the first trench and the second trench. It will however be appreciated that the selector element may be arranged fully in the recess or at least partly in the recess and partly in the trench. The selector element material may alternatively be formed either before or after the formation of the memory layer. This can provide flexibility and can improve the process flow. Examples of selector element materials include, for example, chalcogenide material. For example, GeSbTe formed according to the present methods can be used as a memory element in PCRAM. For example, amorphous GeSe, GeTe, ternary germanium layers, quaternary germanium layers such as GeAsSiTe or GeAsSeTe formed according to methods according to the present disclosure, can be used in OTS selectors.

Suitably, the selectors may be electrically separated. Accordingly, neighboring cells formed in a single layer may be specifically addressed.

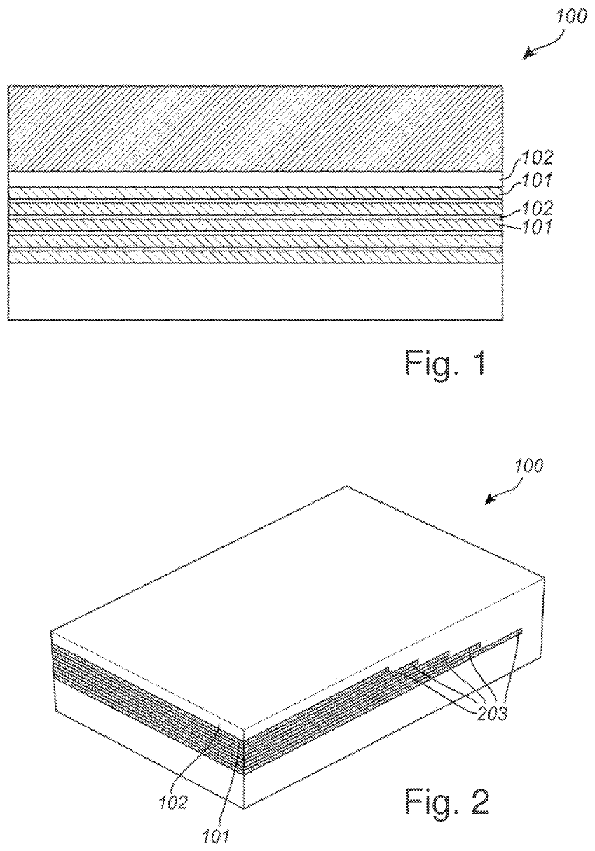

An exemplary manufacturing process of a 3D semiconductor device 10 will now be described with reference to FIGS. 1-13, which illustrate examples and embodiments of the disclosed technology.

FIG. 1 illustrates a vertical stack 100 that may be provided by deposition of layers of a first 101 and a second type 102. Any suitable deposition process may be used, such as atomic layer deposition (ALD), chemical vapor deposition (CVD), physical vapor deposition (PVD), etc. The stack 100 may comprise multiple alternating layers, e.g., arranged such that every other layer may be of the first type 101 and every other layer of the second type 102. The material of the first layer type 101 and the second layer type 102 may be any suitable material allowing the layers 101, 102 to be removed selectively to each other, e.g., such that the first layer 101 is removed, and not the second layer 102, or vice versa, e.g., using an etching process. The first layer 101 may comprise a first electrically insulating material, such as, for example, an oxide. The second layer 102 may comprise a second electrically insulating material, such as, for example, a nitride.

In FIG. 2, a staircase connection structure 203 can be provided in the vertical stack 100. The staircase connection structure 203 may be formed by repeatedly patterning the layers 101, 102 of the vertical stack 100 such that each vertical level of the stack 100 may be is individually accessible or contacted from above (or below e.g., depending on the direction of the staircase connection structure 203). The staircase connection structure 203 may be arranged at the portion of the vertical stack 100 that may form an end portion of each of a plurality of fins. Thus, the staircase connection structure 203 can allow for each of the stack levels of the fins to be individually contacted.

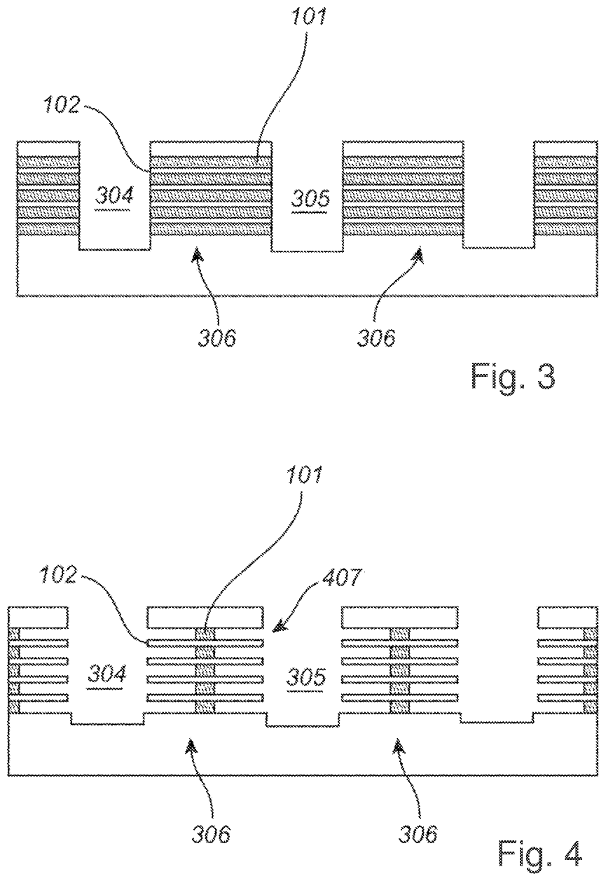

In FIG. 3, trenches have been formed in the vertical stack 100 of alternating layers of the first layer type 101 and the second layer type 102. A first trench 304 and a second trench 305 may be formed in a parallel fashion, such that the remaining part of the stack 100 arranged between the trenches 304, 305 may define a fin 306. A non-limiting example of a cross-dimension depth of a trench 304, 305 may be around 90 nm.

In some embodiments, the trenches 304, 305 may be formed by recessing portions of the vertical stack 100. In some embodiments, instead of providing a vertical stack 100 and subsequently recessing portions of the vertical stack 100, the layers 101, 102 of the vertical stack 100 may be provided such that trenches 304, 305 are adjacent to the vertical stack 100. For example, the layers 101, 102 of the vertical stack 100 may be deposited with the desired width. In some instances, the areas reserved for the trenches 304, 305 may be masked such that after the layers 101, 102 are deposited for the vertical stack 100, the trenches 304, 305 may be provided from the masked areas.

In FIG. 4 the first layer type 101 of the vertical stack 100 is recessed (e.g., partly etched) to form recesses 407 extending into the fin 306. In other words, the material of the first layer type 101 may be recessed from both sides of the fin 306 in a lateral direction into the fin 306. Thus, a part of the material the first layer type 101 may be removed until some of the first layer type 101 remains, separating the recesses 407 arranged on the same vertical level of the stack 100. The resulting structure is illustrated in FIG. 4, wherein each level of the stack 100 comprises two recesses 407 that are separated by the remaining material of the first layer type 101 in the middle of the fin 306. In one non-limiting example, about 65 nm of the first layer type 101 may be selectively recessed (removed) by etching into the recess 407 and about 20 nm may remain of the first layer type 101 in the recess 407. This remaining part of the first layer type 101, which may include an electrically insulating layer, may serve as a supporting line and word line (WL) isolation between the lateral sides of the fin 306.

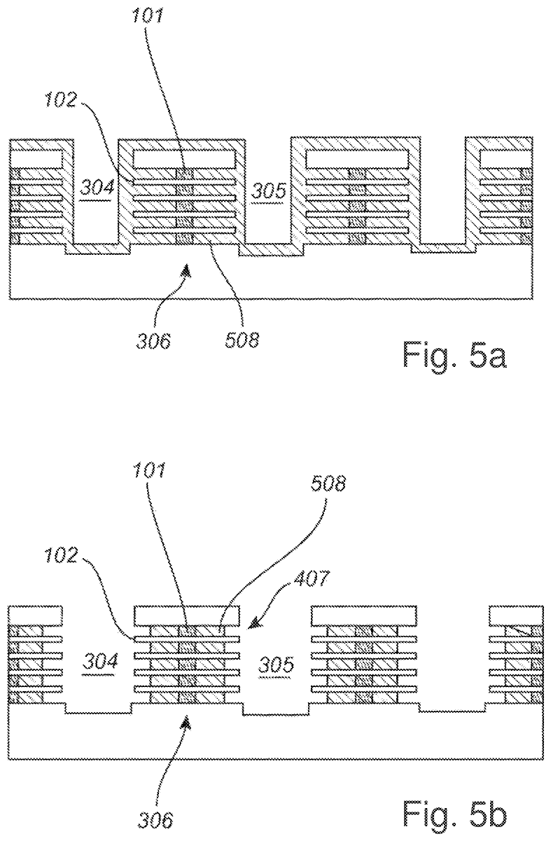

FIGS. 5a and 5b show the formation of a first electrode material of a lateral stack, resulting in a word line (WL). In FIG. 5a, the process of forming the first electrode 508 is performed by covering the fin and the trenches 304, 305 with a first conductive material 508. In some embodiments, one or more portions of the trenches 304, 305 may or may not be covered with the first electrode material 508. In some instances, the first electrode material 508 may be provided using a deposition process such as ALD. FIG. 5b shows the stack after the first conductive material 508 has been removed or etched away and at least partly recessed back into the recess 407 of fin 306. As illustrated in the present figure, the resulting structure may thus be a new recess 407 that extends into the fin and whose depth is defined by the first electrode material present at the “bottom” of the recess 407. This first conductive material forming the first electrode 508, and thus the WL, may be any suitable material such as, in a non-limiting example, a composition of titanium nitride/tungsten (TiN/W), which can provide excellent WL conductivity properties. In some embodiments, the recessing may be performed by wet or dry etching with an etch rate that may be tightly controlled to provide a consistent WL resistance and WL width. In a non-limiting example, the remaining WL width may be about 40 nm by etching away about 25 nm of the WL. In some embodiments, the first electrode material 508 may be provided with the desired depth in the recess 407 (e.g., as shown in FIG. 5b) without a subsequent recessing process.

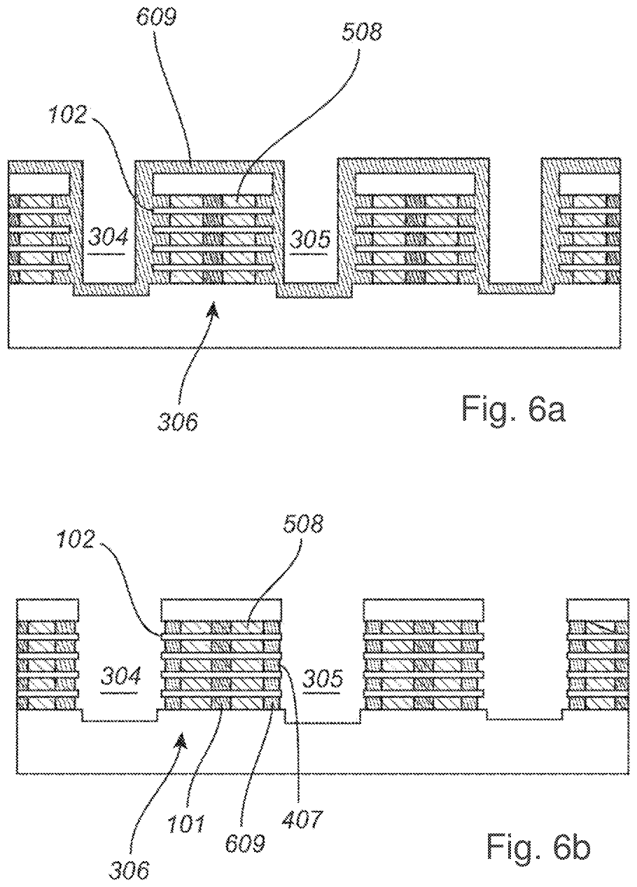

FIG. 6a shows the formation of a memory element 609 according to a prior art technique in which a memory element material 609 is deposited using a blanket layer deposition technique. In this process, both the trenches 304, 305 and the fin may be covered by the memory element material 609. In some embodiments, one or more of portions of the trenches 304, 305 may or may not be covered with the memory element material 609. This process has as a disadvantage that the memory element material 609 needs to be at least partially recessed back into the recess 407 of the lateral stack, thus yielding a structure as shown in FIG. 6b. Using processes according to the present disclosure, which involve selective deposition of a memory element material, a step of at least partially recessing back can be avoided.

Thus, in FIG. 6b, a memory element 609 is formed by selectively depositing a memory element material comprising germanium, a pnictogen, and a chalcogen, thereby filling each recess 407 with a memory element material 609. In a non-limiting example, a width of about 20 nm of the memory element material may remain in the recess 407 of the lateral stack. This process of forming is suitably performed by means of a method for selectively depositing a layer comprising germanium, a pnictogen, and a chalcogenide, as described herein.

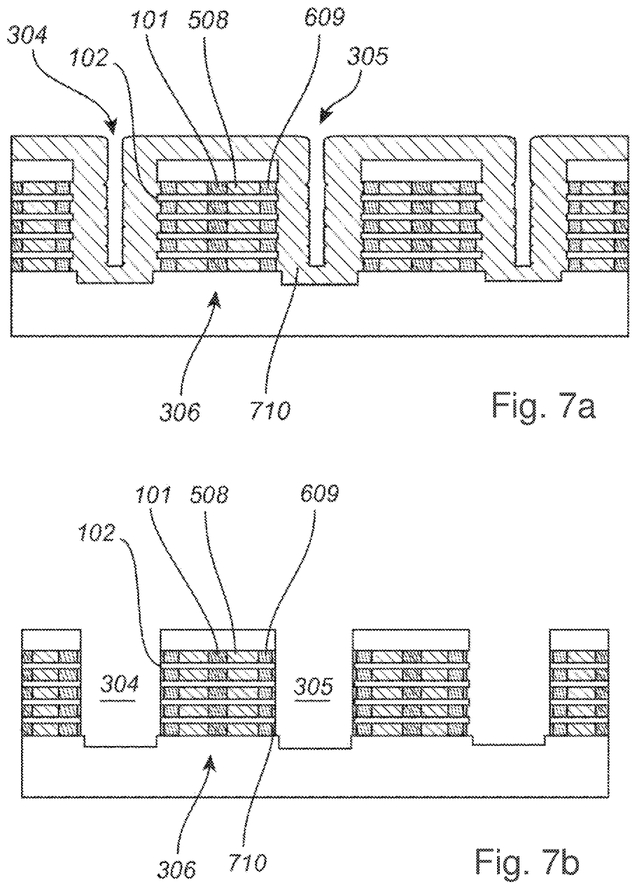

FIGS. 7a and 7b illustrate further steps of forming a middle electrode. The middle electrode 710 may be formed by covering both the fin 306 and the trenches 304, 305 with a second conductive material 710, as may be seen in FIG. 7a. In some embodiments, the second conductive material 710 may or may not cover one or more portions of the trenches 304, 305. In FIG. 7b, the stack is shown after the second conductive material 710 has been etched away and at least partly recessed back into the recess 407. In a non-limiting example, this second conductive material 710 may any suitable material as, e.g., titanium nitride (TiN) with a width of about 5 nm remaining in the recess 407 of the lateral stack. In some embodiments, the second conductive material 710 may be provided with the desired depth in the recess 407 (e.g., as shown in FIG. 7b) without a subsequent recessing process.

It will be noted that the above illustrated processes for providing the first electrode 508, the memory element 609, and the middle electrode 710 are merely examples for illustrating the disclosed technology. In particular, the internal order of the steps may be switched, resulting in other lateral stack configurations than the one shown in the above figures.

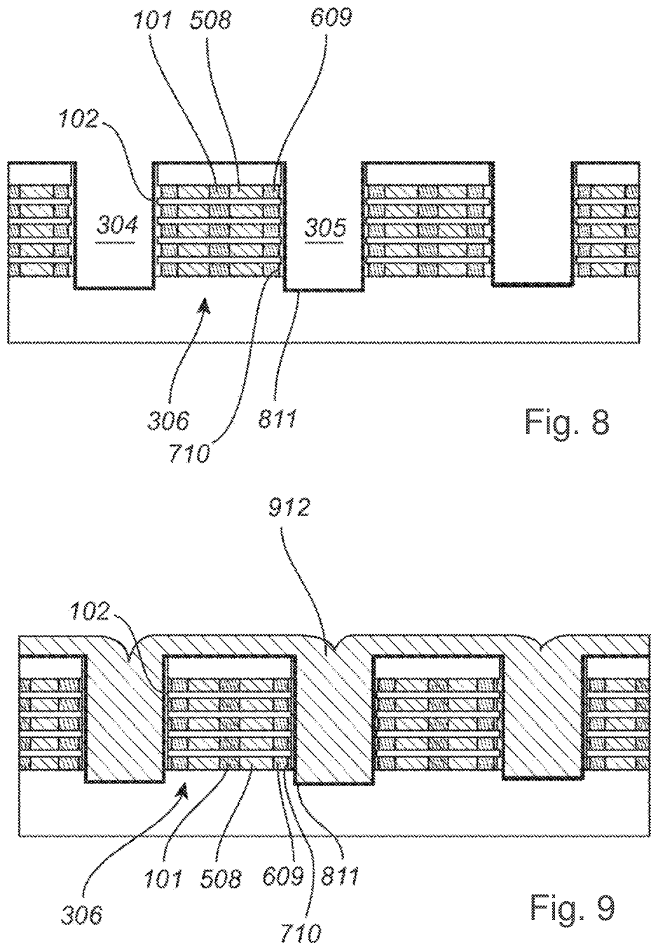

In FIG. 8, the selector element is formed. The selector element may be formed by providing a selector element material 811 in the trenches 304, 305. The selector element material 811 may be arranged to cover or line the walls of the trenches 304, 305, and may, in case there remain any recesses at the middle electrode 710, at least partly extend into the fin. The order of forming the selector element 811 and the memory element 609 in the lateral stack may be interchanged, which makes the manufacturing method compatible with different memory and selector technologies and may further improve the device operation and simplify the process flow. In a non-limiting example, the thickness of the selector material 811 may be about 5 nm.

In FIG. 9, a second electrode material 912 can be provided in each one of the first trench 304 and the second trench 305. The trenches 304, 305 may be completely filled with the second electrode material 912 in some instances. This process may be performed using a deposition process, such as ALD, CVD, or a combination thereof. This second electrode 912 may form the bit line (BL) in the final semiconductor device 10. In a non-limiting example, the thickness may be about 40 nm and the material used may be any suitable material as, e.g., tungsten (W) which may reduce BL resistance.

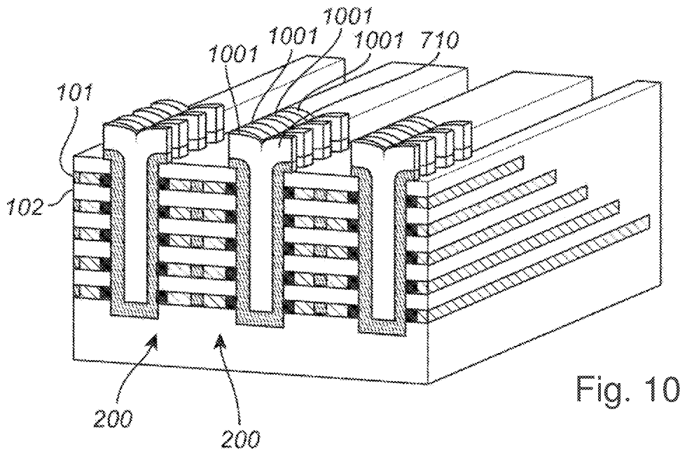

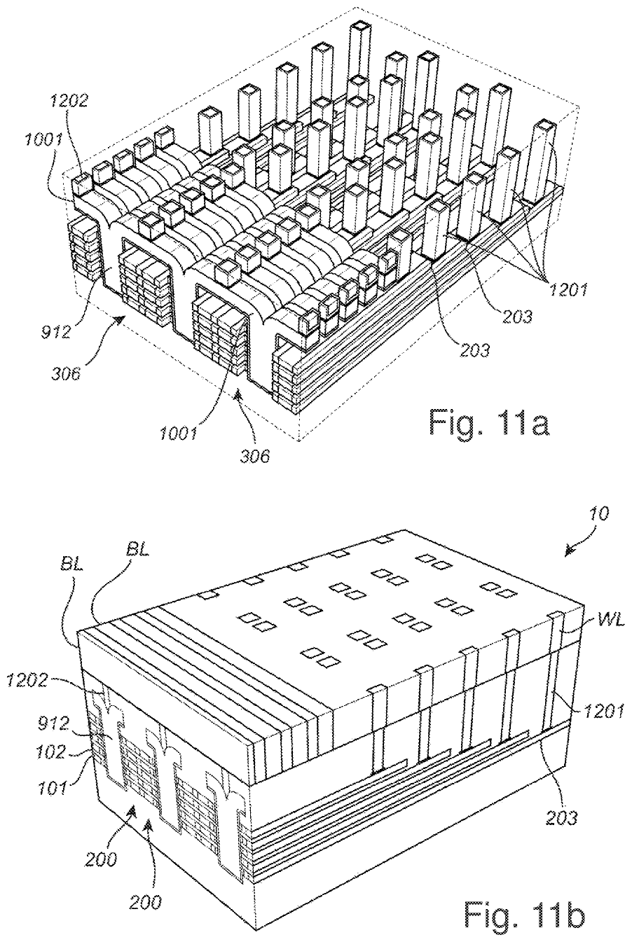

FIG. 10 illustrates in a three-dimensional view of a semiconductor device 10 that may be the result of a method similar to the one described above in connection with the previous embodiments. However, the disclosed example differs in that the memory element 609 (or selector element 811) may be deposited together with the middle electrode 710 as illustrated in FIG. 11. In the following, it may be understood that in some embodiments, the relative positions and the order of formation between the memory element 609 and the selector element 811 can be interchanged.

In the present example, the second electrode material 912 may be formed or patterned into a plurality of contact structures 1001, which, e.g., may extend between two or more fins (e.g., neighboring fins). The contact structures 1001 may, e.g., be formed by cutting the material, e.g., etching away certain portions of the electrode material, along the fins such that different portions of each fin may be selectively addressed. By patterning, or cutting also the selector element material and the middle electrode 710 along the fin, a plurality of individually addressable cells may be formed along each stack level of the fin. In other words, a plurality of functionally separated cells may be formed on each level of the stack 100. Adjacent cells may hence be defined, or separated from each other, by removing the selector material and the middle electrode material between the contact structures formed of the second electrode material 912. In FIG. 10, the resulting contact structures may be shaped as dots configured to connect the cell stacks arranged at both sides of a trench 304, 305 to a common bit line (BL, not shown).

In various embodiments disclosed herein, the memory and selector elements 609, 811 may also be formed in multiple alternating layers. This means that the processes described above can be performed multiple times depending on the number of layers. As used herein, lining can be understood as a process of covering a surface or wall with a layer of a material.

As described herein in embodiments referring to the memory 609 or selector elements 811, these features can be interchanged in their relative positions and/or the order of formation.

FIG. 11a illustrates a three-dimensional view of a 3D semiconductor device 10 according to an embodiment, in which the second electrode material 912 has been patterned into lines crossing the fins. The staircase contact structure 203 and the second electrode material lines 912 may be provided with contact structures 1201, 1202, such as, e.g., vertical via connections, to allow the plurality of memory device (or cells) 200 to be connected to a respective word line WL and/or bit line BL. Such a structure is illustrated in FIG. 11b.

Alternatively, after forming the trenches as explained in FIG. 3, the trenches may first be refilled with insulating material where after hole openings are formed before proceeding to the next step as explained in FIG. 4 (e.g., formation of the selector and memory elements by the different deposit and recess steps). It can have the advantage that no further patterning and lithography steps are needed as described in FIG. 11a. FIG. 11b is a perspective view of a semiconductor device 10 that may be similarly configured as the embodiments discussed above in connection with the previous figures. However, in the present example, the semiconductor device 10 can be provided with a plurality of bit lines BL and word lines WL configured to address the plurality of cells 200 of the 3D semiconductor device 10. Each bit line BL may be electrically connected to a respective second electrode 912 via the second electrode contacts 1202 and be arranged in a parallel grid crossing the fins. Further, each level of the staircase structure 203 of each fin may be connected to a respective word line WL by the vertical staircase contacts 1201. As indicated in FIG. 11b, the bit lines BL and the word lines WL may be arranged in a common layer, embedded in an insulating material in some embodiments.

It will be appreciated that, as configured, memory cells are formed on opposing sides of each the first layers 101 by depositing simultaneously in the first and second trenches 304, 305. Thus formed memory cells formed on opposing sides of each of the first layers 101 are electrically connected to separate contact structures 1201 through respective word lines, such that they are individually or independently accessible or bit-addressable. The resulting memory device 10 can have higher bit density compared to memory devices in which the memory cell stacks formed on opposing sides are not individually or independently accessible or bit-addressable.

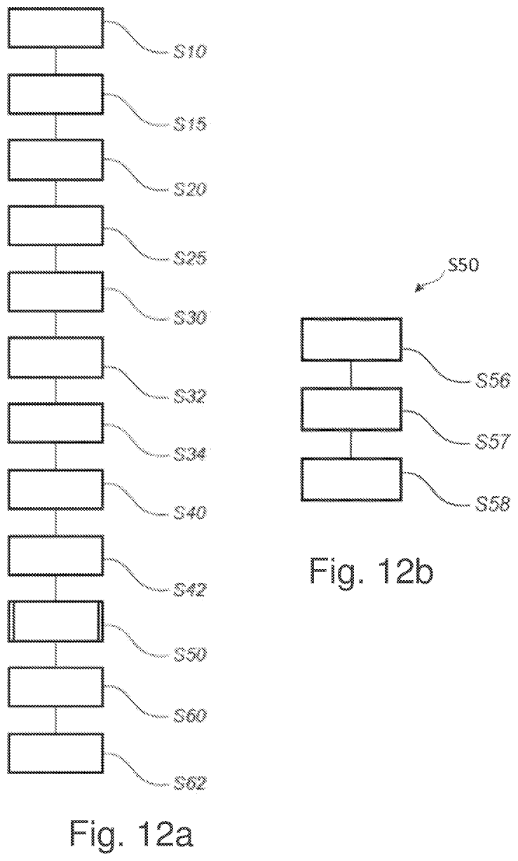

FIG. 12a schematically outlines the steps of exemplary methods to fabricate a semiconductor device 10 according to the above-described examples and embodiments. According to FIG. 12a , the method may comprise the steps of: providing S 10 a vertical stack of alternating layers of a first layer type and a second layer type; providing S 15 the vertical stack with a staircase connection structure; forming S 20 a first trench and a second trench in the vertical stack, the first trench and the second trench defining a fin; recessing S 25, from the first trench and from the second trench, the first layer type to form recesses extending into the fin; providing S 30 a first electrode in each recess by filling S 32 each recess with a first conductive material and recessing S 34 at least some of the first conductive material back into the recess; providing S 40 a second electrode in each one of the first trench and the second trench by forming S 42 a second electrode material into a plurality of contact structures; providing S 50, for each recess, a lateral stack comprising a memory element, a middle electrode and a selector element, the lateral stack stacked in a lateral direction and extending between the first electrode and the second electrode, thereby forming a memory device; connecting S 60, via the staircase connection structure, the first electrode in each recess to a respective word line; and connecting S 62 each one of the plurality of contact structures to a respective bit line. It shall be noted that the deposition of the memory element in step S 50 is suitably carried out by means of a method for deposing a layer comprising germanium, a pnictogen, and a chalcogen as described herein.

As another example, as illustrated in FIG. 12b, in some embodiments, the step of providing S 50 the lateral stack may comprise the steps of: lining S 56 each recess with one of a selector element material or a memory element material to form one of the selector element or the memory element, respectively; filling S 57 each recess with a second conductive material forming the middle electrode; and forming S 58 the other of the selector element or the memory element by providing the other of the selector element material or the memory element material in the first trench and the second trench.

The materials described in connection with the above figures should merely be seen as illustrating examples. Other material combinations are also possible, such as, e.g., ruthenium (Ru), cobalt (Co), or TiN for the WL and/or the BL, which may provide advantageous electrical conductivity properties.

Further described herein is a system comprising one or more reactor chambers. The system further comprises a blocking agent storage module, a germanium precursor storage module, a pnictogen reactant storage module, and a chalcogen reactant storage module. The blocking agent storage module comprises a blocking agent. Advantageously, the blocking agent may comprise an alkylaminosilane. The germanium precursor storage module comprises a germanium precursor. The antimony reactant storage module comprises a pnictogen reactant. The tellurium reactant storage module comprises a chalcogen reactant.

In some embodiments, the system further comprises a controller. The controller is configured for causing the system to provide the blocking agent to one or more of the reaction chambers in an area-selective blocking pulse. In addition, the controller is configured to provide a sequence of deposition pulses to the one or more reactor chambers after the area-selective blocking pulse. The sequence of deposition pulses comprises a germanium pulse, an antimony pulse, and a tellurium pulse. The germanium pulse comprises the provision of the germanium precursor from the germanium precursor storage module to the one or more reactor chambers. The pnictogen pulse comprises the provision of the pnictogen reactant from the pnictogen reactant storage module to the one or more reactor chambers. The chalcogen pulse comprises the provision of the chalcogen reactant from the chalcogen precursor storage module to the one or more reactor chambers.

In some embodiments, the controller is configured for causing the system to perform a method for depositing germanium, a pnictogen, and a chalcogen, as described herein.

During the methods for selectively depositing a material comprising germanium, a pnictogen, and a chalcogen, various reactant vapors are fed into a reaction chamber. In such applications, the reactant vapors are often gaseous at ambient pressures and temperatures. Alternatively, the vapors of source chemicals that are liquid or solid at ambient pressure and temperature may be used. These substances may be heated, e.g. in their storage module, to produce sufficient amounts of vapor for the reaction process, such as atomic layer deposition (ALD) or chemical vapor deposition (CVD). CVD may call for continuous streams of reactant vapor, and ALD may call for continuous streams or pulsed supply, depending on the configuration. In both cases it can be important to know with some accuracy the amount of reactant supplied per unit time or per pulse in order to control the doses and effect on the process. However, this can be difficult.

Liquid precursors (or precursor-solvent mixtures) can be evaporated in a vaporizer such as a liquid injection vaporizer, to form a reactant vapor to be delivered to the reactor or reaction chamber. However, in some devices, the pressure and temperature at portions of the system between the vaporizer and the reaction chamber may vary. Variations in the temperature and/or pressure within the process control chamber (or other such variations along the pathway between the vaporizer and the reaction chamber) may cause the vaporized reactant to condense into droplets of liquid. Condensation of reactant vapor upstream of the reaction chamber can result in the presence of liquid droplets within the reaction chamber, which can cause defects in the processed substrate (e.g., processed wafer) and reduce processing yields.

Thus, there remains a continuing demand for improved formation and delivery of germanium precursors, pnictogen reactants, and chalcogen reactants to the reactor.

Accordingly, in some embodiments, the controller is configured for controlling the temperature of the blocking agent storage module, for controlling the temperature of the germanium precursor storage module, for controlling the temperature of the pnictogen reactant storage module, and/or for controlling the temperature of the chalcogen reactant storage module. In some embodiments, one or more of these temperatures are controlled based on a temperature measured in the reaction chamber, e.g. based on the temperature of the substrate in the reaction chamber. For example, the temperature in any one of the aforementioned storage modules may be inversely related to the temperature in the reaction chamber.

Additionally or alternatively, the controller may be configured to control the pressure of the blocking agent storage module, for controlling the pressure of the germanium precursor storage module, for controlling the pressure of the pnictogen reactant storage module, and/or for controlling the pressure of the chalcogen reactant storage module. In some embodiments, the aforementioned pressures may be controlled based on a temperature in the reaction chamber. For example, the pressure in any one of the aforementioned storage modules may be inversely related to the temperature in the reaction chamber.

In some embodiments, the blocking agent storage module, the germanium precursor storage module, the pnictogen reactant storage module, and/or the chalcogen reactant storage module is operationally connected to vaporizer. Optionally, each storage module may be operationally connected to a separate vaporizer. Optionally, one or more of the vaporizers comprise an atomizer for atomizing a precursor or reactant. Advantageously, the system further comprises one or more filters for capturing and evaporating any droplets that are not vaporized in the vaporizer.

In some embodiments, the system includes a first thermal zone that is maintained at a first temperature and a second thermal zone that is maintained at a second temperature. In various embodiments, the second temperature of the second thermal zone can be higher than the first temperature of the first thermal zone. Advantageously, the first thermal zone comprises the storage modules, and the second thermal zone comprises the reaction chamber, and optionally the atomizer, the vaporizer, and/or the filter. In various embodiments, for example, the second temperature can be higher than the first temperature by a temperature difference in a range of 5° C. to 50° C., in a range of 5° C. to 35° C., or in a range of 10° C. to 25° C. It shall be understood that the temperature inside the reaction chamber is a process temperature which can be even higher than the second temperature.

In some embodiments, the system includes a manifold. The manifold is configured for assisting in bringing the blocking agent, the germanium precursor, the chalcogen reactant, and the pnictogen reactant from their respective storage modules to the reaction chamber. In some embodiments, the manifold has an internal bore, at least one distribution channel extending generally in a plane intersecting the longitudinal axis of the bore, and a plurality of internal supply channels connecting the distribution channel and the bore. Inert gas can be constantly supplied to an upstream inlet of the bore, so as to provide a “sweep” now from the top to the bottom of the bore. The distribution channel is connected to the blocking agent storage module, the germanium precursor storage module, the pnictogen reactant storage module, and the chalcogen reactant storage module. Optionally, the connection to any one of these modules comprises a vaporizer. In some embodiments, the distribution channel can follow a circular curvature.

The supply channels can be connected to or merge with the bore at multiple, spaced-apart locations about a longitudinal axis of the bore. In some embodiments, the supply channels can also connect with the bore in a tangential fashion (as viewed in a transverse cross-section) so as to promote swirling and further enhance mixing within the bore. By introducing each reactant gas to the bore at a plurality of locations about the bore in this manner, mixing is promoted at the point of injection into the bore. The constant flow of inert gas can serve to purge the mixing volume inside the bore, and can also serve as a diffusion barrier between pulses of reactant gas. The constant now of inert gas can also serve as a diffusion barrier to protect against reactants migrating and stagnating in the bore upstream of the merge point for reactants. In embodiments, the bore can have length-to-diameter (L/D) ratio for each reactant of greater than 3, greater than 5, or greater than 10, where the L/D ratio is measured from point of merger with the bore for that reactant to the outlet of the bore, and the diameter is an average diameter along the reactant path length along the bore. The volume of the bore can thus be reduced as compared to conventional ALD systems, aiding in quick diffusion of the reactants and precursors across the bore prior to delivery into the reaction chamber. Indeed, it is of particular interest to quickly ensure diffusion of the reactant across the entire diameter of the bore where a dispersion mechanism (e.g., showerhead assembly) intervenes between the manifold and the reaction space. If concentration uniformity is not achieved within the bore before the gases enter the dispersion mechanism, the non-uniformity will be carried through the dispersion mechanism and into the reaction space, which can result in non-uniform deposition. The features of the distributed supply channels and the narrow and long bore, individually and collectively, facilitate a uniform distribution of reactant across the cross-section of the cylindrical “plug” of each reactant pulse. The manifold is configured to deliver gases to an injector (e.g., a showerhead) for distribution into a reaction chamber.

Embodiments can also include one or more heaters configured to maintain thermal uniformity within the manifold, reducing the risk of decomposition or condensation within the manifold. Such heaters may comprise a heating element which may be positioned, for example, adjacent to the manifold.

In some embodiments, the reaction chamber comprises a showerhead injector, or simply “showerhead”, for providing the blocking agent, the germanium precursor, the pnictogen reactant, and the chalcogen reactant to the reaction chamber. In some embodiments, the showerhead includes a body having an opening, a first plate positioned within the opening and having a plurality of slots, a second plate positioned within the opening and having a plurality of slots. In some embodiments, each of the first plate plurality of slots are concentrically aligned with the second plate plurality of slots. In some embodiments, one or more of the blocking agent, the germanium precursor, the pnictogen reactant, and the chalcogen reactant are provided to the reaction chamber via the first plate plurality of slots, and the other substances selected from the blocking agent, the germanium precursor, the pnictogen reactant, and the chalcogen reactant are provided to the reaction chamber via the second plate plurality of slots.

In some embodiments, the first plate slots may extend towards the second plate slots. In some embodiments, the first plate slots may extend to a bottom surface of the second plate slots. The first and second plate slots may be oriented in a plurality of rings, wherein adjacent rings are offset with respect to one another. The first and second plate plurality of slots may be oriented in a plurality of rings, wherein every other ring is in alignment. A gap may be formed between each of the plurality of first slots and each of the plurality of second slots, and wherein the gap varies between 0.575 mm and 0.800 mm. A gap may be formed within each of the plurality of first slots, and wherein the gap varies between 0.636 mm and 1.100 mm

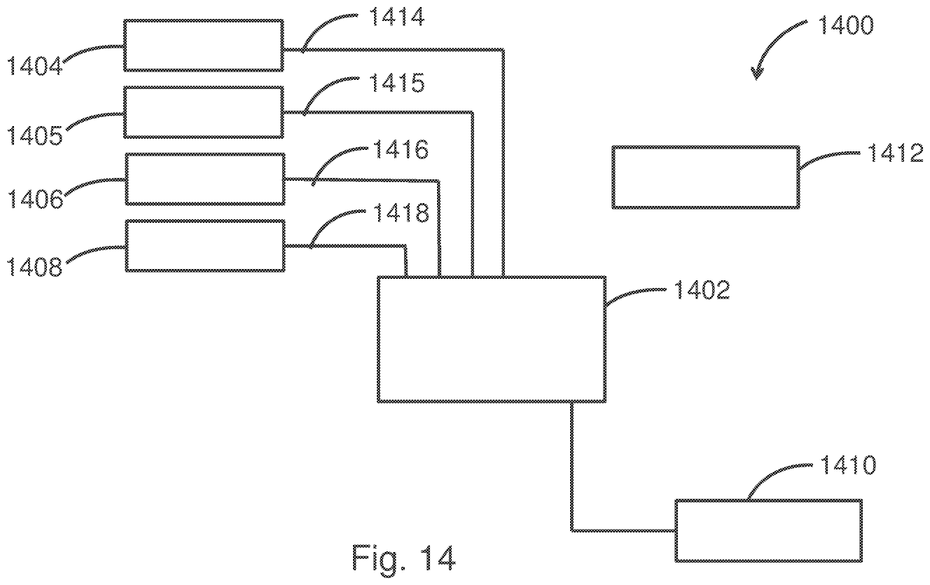

FIG. 14 illustrates a system (1400) in accordance with yet additional exemplary embodiments of the disclosure. The system (1400) can be used to perform a method as described herein and/or form a structure or device portion as described herein.

In the illustrated example, the system (1400) includes one or more reaction chambers (1402), and a number of gas sources (1404)-(1408), and a controller (512). The gas sources comprise a blocking agent storage module (1404), a germanium precursor storage module (1405), a pnictogen reactant storage module (1406), a chalcogen reactant storage module (1408), and an exhaust (510). Of course, other gas sources such as gas lines may be used as an alternative to the storage modules.

The reaction chamber (1402) can include any suitable reaction chamber, such as an ALD or CVD reaction chamber. Advantageously, the reaction chamber (1402) is an ALD reaction chamber.

The blocking agent storage module (1404) comprises a blocking agent. The germanium precursor storage module comprises a germanium precursor. The pnictogen reactant storage module comprises a pnictogen reactant. The chalcogen reactant storage module comprises a chalcogen reactant. Suitable blocking agents, germanium precursors, pnictogen reactants, and chalcogen reactants are mentioned elsewhere herein.

The gas sources (1404)-(1408) can be coupled to the reaction chamber (1402) via lines (1414)-(1418), which can each include flow controllers, valves, heaters, and the like. Optionally, the system can include any suitable number of additional gas sources. Optionally, the system can further describe a purge gas source (not shown in FIG. 14) which includes one or more inert gases as described herein.

Exhaust (1410) can include one or more vacuum pumps.

Controller (1412) includes electronic circuitry including a processor, and software to selectively operate valves, manifolds, heaters, pumps and other components included in the system (1400). Such circuitry and components operate to introduce precursors, reactants, and optionally purge gases from the respective sources (1404)-(1408). The controller (1412) can control timing of gas pulse sequences, temperature of the substrate and/or reaction chamber, pressure within the reaction chamber, and various other operations to provide proper operation of the system (1400). The controller (1412) can include control software to electrically or pneumatically control valves to control flow of precursors, reactants and purge gases into and out of the reaction chamber (1402). Controller (1412) can include modules such as a software or hardware component, e.g., a FPGA or ASIC, which performs certain tasks. It shall be understood that where the controller includes a software component to perform a certain task, the controller is programmed to perform that particular task. A module can advantageously be configured to reside on the addressable storage medium, i.e. memory, of the control system and be configured to execute one or more processes.

It will be appreciated that there are many arrangements of valves, conduits, precursor sources, and purge gas sources that may be used to accomplish the goal of feeding gases into the reaction chamber (1402). Further, as a schematic representation of a system, many components have been omitted for simplicity of illustration, and such components may include, for example, various valves, manifolds, purifiers, heaters, containers, vents, and/or bypasses.

During operation of reactor system (1400), substrates, such as semiconductor wafers (not illustrated), are transferred from, e.g., a substrate handling system to reaction chamber (1402). Once the substrate(s) are transferred to the reaction chamber (1402), one or more gases from the gas sources (1404)-(1408), such as precursors, reactants, carrier gases, and/or purge gases, are introduced into reaction chamber (1402).

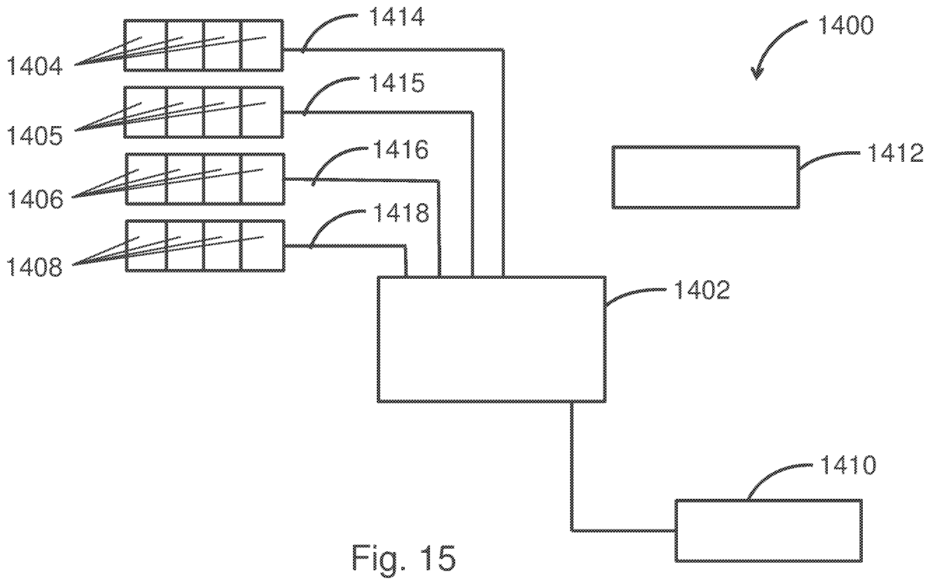

In some embodiments, the reaction chamber comprises more than one blocking agent storage module, more than one germanium precursor storage module, more than one pnictogen reactant storage module, and/or more than one chalcogen reactant storage module. An embodiment of such a system is illustrated in FIG. 15. Indeed, the system (1400) shown in FIG. 15 is similar to that shown in FIG. 14, except that it comprises multiple blocking agent storage modules, multiple pnictogen reactant storage modules, and multiple chalcogen reactant storage modules. Such use of multiple storage modules allows increasing the rate at which blocking agent, reactants, and/or precursors are provided to the reaction chamber. This may increase throughput. Further details of systems in which multiple identical storage modules may be used are described in U.S. Pat. No. 9,238,865, which is hereby incorporated by reference in its entirety.

Thus, in some embodiments, the system comprises a plurality of blocking agent storage modules. The blocking agent storage modules suitably comprise an identical blocking agent. The controller is configured for causing the system to simultaneously inject blocking agent, during the area-selective blocking agent pulse, from the blocking agent storage modules into the reaction chamber.

Additionally or alternatively, the system may comprise more than one germanium precursor storage module. The germanium precursor storage modules each comprise an identical germanium precursor. The controller is configured for causing the system to simultaneously inject germanium precursor, during the germanium pulses, from each of the germanium precursor storage modules into the reaction chamber.

Additionally or alternatively, the system may comprise more than one pnictogen reactant storage module. The plurality of pnictogen reactant storage modules each comprise an identical pnictogen reactant. The controller is configured for causing the system to simultaneously inject the pnictogen reactant, during the pnictogen pulses, from each of the pnictogen reactant storage modules into the reaction chamber.

Additionally or alternatively, the system may comprise a plurality of chalcogen reactant storage modules. The chalcogen reactant storage modules each comprise an identical chalcogen reactant. The controller is configured for causing the system to simultaneously inject the chalcogen reactant, during the chalcogen pulses, from each of the chalcogen reactant storage modules into the reaction chamber.

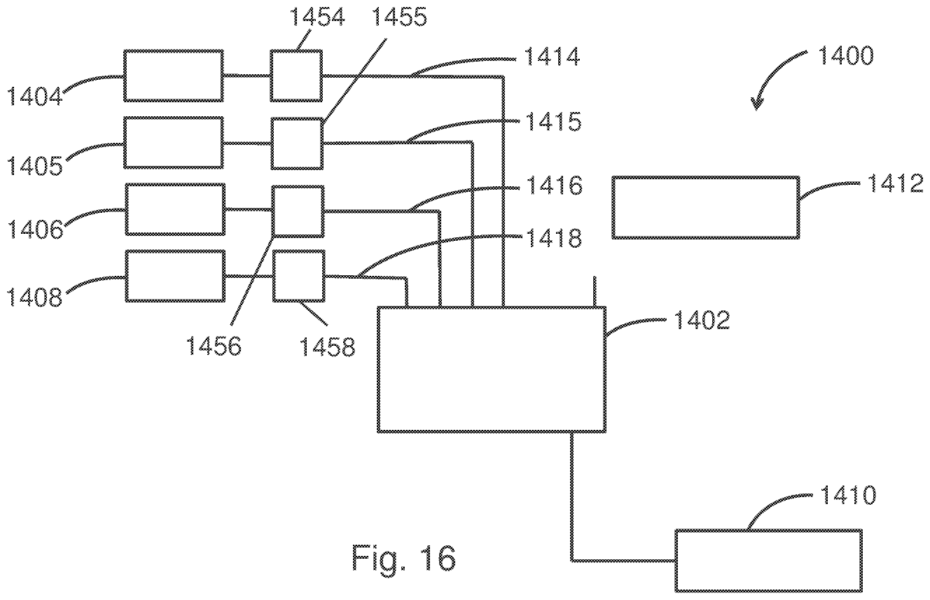

In some embodiments, the reaction chamber comprises a blocking agent buffer module, a germanium precursor buffer module, a pnictogen reactant buffer module, and/or a chalcogen reactant buffer module. An embodiment of such a system is illustrated in FIG. 16. The system (1400) of FIG. 16 is similar to that of FIGS. 14 and 15 except in that it comprises four buffer modules (1454)-(1458). In particular, the system (1400) comprises a blocking agent buffer module (1454) which is configured to receive blocking agent from the blocking agent storage module (1404), and which is configured to provide blocking agent to the reaction chamber (1402). In addition, the system (1400) comprises a germanium precursor buffer module (1455) which is configured to receive germanium precursor from the germanium precursor storage module (1405), and which is configured to provide germanium precursor to the reaction chamber (1402). In addition, the system (1400) comprises a pnictogen reactant buffer module (1456) which is configured to receive pnicgoten reactant from the pnictogen reactant storage module (1406), and which is configured to provide pnictogen reactant to the reaction chamber (1402). In addition, the system (1400) comprises a chalcogen reactant buffer module (1458) which is configured to receive chalcogen reactant from the chalcogen reactant storage module (1408), and which is configured to provide chalcogen reactant to the reaction chamber (1402).

The buffer modules may temporarily store blocking agent, germanium precursor, pnictogen reactant, and/or chalcogen reactant, before releasing a stored quantity of blocking agent, germanium precursor, pnictogen reactant, and/or chalcogen reactant. Thus, the buffer modules may allow delivering a large amount of blocking agent, germanium precursor, pnictogen reactant, and/or chalcogen reactant to the reaction chamber in a short time. This can be done, for example, by temporarily storing blocking agent, germanium precursor, pnictogen reactant, and/or chalcogen reactant in a readily deliverable form. Suitable buffer modules are described in U.S. Pat. No. 6,039,809, which is hereby incorporated by reference in its entirety.

Thus, in some embodiments, a system as described herein may further comprise a blocking agent buffer module. The blocking agent buffer module is configured to receive the blocking agent from the blocking agent storage module. The blocking agent buffer module may be configured to provide the blocking agent to the reaction chamber.

In some embodiments, the system further comprises a germanium precursor buffer module. The germanium precursor buffer module is configured to receive the germanium precursor from the germanium precursor storage module. Also, the germanium precursor buffer module is configured to provide the germanium precursor to the reaction chamber.

In some embodiments, the system further comprises a pnictogen reactant buffer module. The pnictogen reactant buffer module is configured to receive the pnictogen reactant from the pnictogen reactant storage module. Also, the pnictogen reactant buffer module is configured to provide the pnictogen reactant to the reaction chamber.

In some embodiments, the system further comprises a chalcogen reactant buffer module. The chalcogen reactant buffer module is configured to receive the chalcogen reactant from the chalcogen reactant storage module. Also, the chalcogen reactant buffer module is configured to provide the chalcogen reactant to the reaction chamber.

In some embodiments, the blocking agent buffer module is configured to receive blocking agent from more than one blocking agent storage module. In some embodiments, the germanium precursor buffer module is configured to receive germanium precursor from more than one germanium precursor storage module. In some embodiments, the pnictogen reactant buffer module is configured to receive the pnictogen reactant from more than one pnictogen reactant storage module. In some embodiments, the chalcogen reactant buffer module is configured to receive the chalcogen reactant from more than one chalcogen reactant storage module.

In some embodiments, the system comprises more than one blocking agent buffer module. Suitably, each blocking agent buffer module may be configured to receive blocking agent from a blocking agent storage module. In some embodiments, the system comprises more than one germanium precursor buffer module. Suitably, each germanium precursor buffer module may be configured to receive germanium precursor from a germanium precursor storage module. In some embodiments, the system comprises more than one pnictogen reactant buffer module. Suitably, each pnictogen reactant buffer module may be configured to receive pnictogen reactant from a pnictogen reactant storage module. In some embodiments, the system comprises more than one chalcogen reactant buffer module. Suitably, each chalcogen reactant buffer module may be configured to receive chalcogen reactant from a chalcogen reactant storage module.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for selectively depositing a material, the method comprising, in the following order:
providing a substrate comprising a first surface and a second surface in a reaction chamber;
providing a surface conditioning agent to the reaction chamber, thereby selectively passivating the first surface and forming a passivated first surface; and,
providing a germanium precursor comprising germanium, a pnictogen reactant comprising a pnictogen, and a chalcogen reactant comprising a chalcogen to the reaction chamber,
thus selectively depositing the material on the second surface relative to the first surface, the material comprising the germanium, the pnictogen, and the chalcogen.

2. The method according to claim 1 wherein the germanium precursor comprises a germanium halide.

3. The method according to claim 1 wherein the pnictogen comprises antimony, and wherein the pnictogen reactant comprises an antimony precursor.

4. The method according to claim 3 wherein the antimony precursor comprises an antimony halide.

5. The method according to claim 1 wherein the chalcogen comprises tellurium, and wherein the chalcogenide precursor comprises a tellurium precursor.

6. The method according to claim 5 wherein the tellurium precursor comprises a tellurium silyl.

7. The method according to claim 1 wherein the surface conditioning agent comprises a silyl moiety, and wherein selectively passivating the first surface comprises selectively forming silyl groups on the first surface.

8. The method according to claim 1 wherein the step of providing a germanium precursor, a pnictogen reactant, and a chalcogen reactant to the reaction chamber comprises a cyclic deposition process comprising a plurality of cycles, the cycles comprising a plurality of pulses, the plurality of pulses comprising, in any order:
providing the germanium precursor to the reaction chamber in a germanium precursor pulse;
providing the pnictogen reactant to the reaction chamber in a pnictogen reactant pulse; and,
providing the chalcogen reactant to the reaction chamber in a chalcogen reactant pulse.

9. The method according to claim 8 wherein the germanium precursor pulse, the pnictogen reactant pulse, and/or the chalcogen reactant pulse are separated from other pulses by means of a purge.

10. The method according to claim 8 wherein the pnictogen reactant pulse precedes the germanium precursor pulse.

11. The method according to claim 1 wherein the second surface comprises a metal nitride or a metal.

12. The method according to claim 11 wherein the second surface comprises titanium nitride or tungsten.

13. The method according to claim 1 wherein the first surface comprises an oxide.

14. The method according to claim 13 wherein the first surface comprises silicon oxide.

15. A method for manufacturing an intermediate memory device structure, the method comprising:
providing a substrate comprising, on an upper surface, a multi-layer stack comprising horizontally alternating first layers and second layers;
the first layers comprising a first material, the first material comprising a dielectric material;
the second layers comprising extremities, the second layers comprising, at least on their extremities, a metal or a metal nitride, the metal or the metal nitride forming an electrode;
forming an opening in the multi-layer stack, thereby exposing the metal or the metal nitride;
selectively depositing a material comprising germanium, a pnictogen, and a chalcogenide on the metal or the metal nitride by means of a method according to claim 1.

16. The method according to claim 15 further comprising, before depositing the germanium chalcogenide, a step of partially recessing the metal or the metal nitride.

17. The method according to claim 15 further comprising depositing a further metal or a further metal nitride on the germanium chalcogenide, thus forming a second electrode.

18. A method for manufacturing a memory device, the method comprising:
providing a fin comprising a plurality of alternating first layers and second layers, the first layers comprising a first surface, the second layers comprising a plurality of wordlines having a second surface, the second surface comprising a metal surface or a metal nitride surface;
selectively depositing a plurality of phase change layers by depositing a material comprising germanium, a pnictogen, and a chalcogenide on the second surface by means of a method according to claim 1;
forming a plurality of electrodes contacting the plurality of phase change structures;
forming a plurality of selectors overlying the plurality of electrodes;
forming a plurality of bitlines overlying the plurality of selectors; and,
forming a plurality of contacts to the wordlines and forming a plurality of contacts to the bitlines, thus forming a memory device.

19. The method according to claim 18 wherein forming a plurality of contacts to the wordlines comprises providing a staircase structure in which sequential wordlines are sequentially contacted.

20. The method according to claim 19, wherein the contacts are shaped as separated lines or dots.
